(19) United States
(12) Patent Application Publication
(10) Pub. No.: US 2006/0164266 A1
(43) Pub. Date: Jul. 27, 2006

(54) Synthesizing a remote controlled clock for data transmission via a digital multimedia link

(75) Inventors: Michael Riedel, Buchbach (DE); Roland Neumann, Bad Toelz (DE)

Correspondence Address: Silicon Edge Law Group LLP, Suite 245, 6601 Koll Center Parkway, Pleasanton, CA, 94566, US

(73) Assignee: INOVA Semiconductors GmbH

(21) Appl. No.: 11/386,559

(22) Filed: Mar. 22, 2006

Related U.S. Application Data
(63) Continuation of application No. PCT/EP03/10524, filed on Sep. 22, 2003.
(63) Continuation of application No. PCT/EP03/10522, filed on Sep. 22, 2003.

(51) Int. Cl. H03M 7/00

(52) U.S. Cl. 341/50

(57) ABSTRACT

A system synthesizes a remote controlled clock across data transmission through a digital multimedia link. A clock is generated at the receiver side that is exactly synchronous to a master clock at the transmitter side. The system includes a clock encoder on the transmitter side, a synchronous serial data transmission system, and a clock decoder on the receiver side. The clock encoder and decoder include counters that count up until predetermined numbers are exceeded and wrap around when those predetermined numbers are exceeded. A clock synthesizer in the clock decoder generates the remote controlled clock. A controller in the clock decoder processes remote and local time stamps and generates control signals that control the clock synthesizer such that the remote controlled clock has the same frequency and the same number of transitions as the master clock received by the clock encoder.

### CROSS REFERENCE TO RELATED APPLICATION

This application is filed under 35 U.S.C. §111(a) and is based on and hereby claims priority under 35 U.S.C. §120 and §365(c) from International Application Nos. PCT/EP2003/010524 and PCT/EP2003/010522, both filed on Sep. 22, 2003. Applications PCT/EP2003/010524 and PCT/EP2003/010522 were published on Mar. 31, 2005, as WO2005/029740 and WO2005/029869, respectively. This application is a continuation of International Application No. PCT/EP2003/010524. International Application No. PCT/EP2003/010524 was pending as of the filing date of this application, and the United States was an elected state in International Application No. PCT/EP2003/010524. The disclosures of International Application No. PCT/EP2003/010524 and International Application No. PCT/EP2003/010522 are incorporated herein by reference.

### TECHNICAL FIELD

The present invention relates to synthesizing a remote controlled clock for data transmission via a digital multimedia link.

### BACKGROUND

Digital satellite systems, DVD players, digital cameras and high definition televisions, as well as PC graphics, games and the Internet, offer a huge amount of digital video and audio data. In order for the digital infrastructure to process this multimedia data effectively, the data should be transmitted and displayed digitally without any loss from analog transmission and display technologies. With the rapid drop in the cost of digital flat panel monitors and displays, there is an increasing interest in the advantages of digital long-distance transmission technology for multimedia data.

Using serial data transmission technology to transmit data between a transmitter side and a receiver side typically requires that a clock at the transmitter side and a clock at the receiver side be exactly synchronous with each other in order to avoid any disturbances of data or even loss of data.

A system is sought that synthesizes a synchronous remote controlled clock across data transmission through a digital multimedia link.

### SUMMARY

A system synthesizes a remote controlled clock across data transmission through a digital multimedia link. A clock is generated at the receiver side that is exactly synchronous to a master clock at the transmitter side.

The system includes a clock encoder on the transmitter side, a synchronous serial data transmission system, and a clock decoder on the receiver side. The clock encoder includes a first transmitter side counter that counts up until a first predetermined number is exceeded and wraps around when the first predetermined number is exceeded. The first transmitter side counter receives a master clock. The clock encoder also includes a second transmitter side counter that counts up until a second predetermined number is exceeded and wraps around when the second predetermined number is exceeded.

The clock decoder includes a first receiver side counter, a second receiver side counter, a controller and a clock synthesizer. The first receiver side counter counts up until the first predetermined number is exceeded and wraps around when the first predetermined number is exceeded. The second receiver side counter counts up until the second predetermined number is exceeded and wraps around when the second predetermined number is exceeded. The clock synthesizer generates a remote controlled clock. The controller controls the clock synthesizer such that the remote controlled clock has the same frequency and the same number of transitions as the master clock received by the first transmitter side counter. The second transmitter side counter outputs its count value as a remote time stamp when the first transmitter side counter wraps around. The second receiver side counter outputs its count value as a local time stamp when the first receiver side counter wraps around.

The controller processes the remote time stamp and the local time stamp using an algorithm and generates control signals that control the clock synthesizer. The controller generates a first difference between a presently valid remote time stamp and a remote time stamp valid before the presently valid remote time stamp. The controller also generates a second difference between a presently valid local time stamp and a local time stamp valid before the presently valid local time stamp. A third difference is the difference between the first difference and the second difference. Then the controller calculates a presently valid time offset by subtracting the third difference from a time offset valid before the presently valid time offset. The controller determines that the remote controlled clock is too slow when the second difference is less than the first difference. The remote controlled clock is too fast when the second difference is greater than the first difference.

The controller increases the frequency of the remote controlled clock when the presently valid time offset has a value greater than zero. The controller decreases the frequency of the remote controlled clock when the presently valid time offset has a value less than zero

A method for synthesizing a remote controlled clock for data transmission through a digital multimedia link includes receiving a master clock, counting up, outputting remote count values and local count values, generating control signals, generating a remote controlled clock, and controlling the remote controlled clock using the control signals.

The method uses an algorithm to generate a first difference between a presently valid first time stamp and a first time stamp valid before the presently valid first time stamp. The method also generates a second difference between a presently valid second time stamp and a second time stamp valid before the presently valid second time stamp. A presently valid time offset is calculated by subtracting from a time offset valid before the presently valid time offset the difference between the first and second differences.

Other embodiments and advantages are described in the detailed description below. This summary does not purport to define the invention. The invention is defined by the claims.

### BRIEF DESCRIPTION OF THE DRAWINGS

The accompanying drawings, where like numerals indicate like components, illustrate embodiments of the invention.

FIG. 1 is a schematic block diagram of a system for synthesizing a remote controlled clock, including a clock encoder and a clock decoder.

FIG. 2 is a schematic block diagram showing the clock encoder and the clock decoder of FIG. 1 in more detail.

FIG. 3 shows an algorithm used by a controller of the clock decoder of FIG. 2.

FIG. 4 is a schematic view of a logical-to-physical mapping of a serial bidirectional multimedia link with which the system of FIG. 1 can be used.

FIG. 5 is a schematic block diagram of a serializer/deserializer architecture of the bidirectional multimedia link of FIG. 4.

FIG. 6 is a more detailed schematic block diagram of the multimedia link architecture of FIG. 4.

FIG. 7 is a schematic view of the downstream frame structure of data transmitted via the bidirectional multimedia link of FIG. 4.

FIG. 8 is a schematic view of an upstream frame structure of data transmitted via the bidirectional multimedia link of FIG. 4.

### DETAILED DESCRIPTION

Reference will now be made in detail to some embodiments of the invention, examples of which are illustrated in the accompanying drawings.

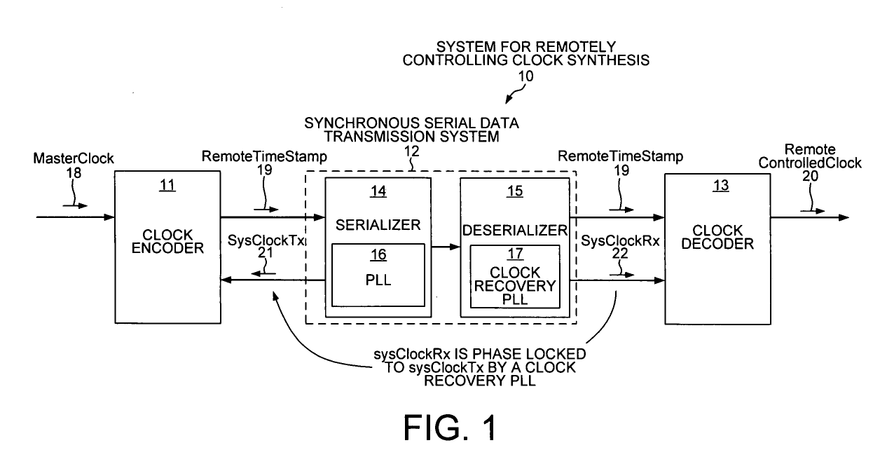

FIG. 1 shows the overall structure of a system 10 for remotely controlling the synthesis of a system clock for data transmitted via a digital multimedia link. System 10 includes a clock encoder 11, a synchronous serial data transmission system 12, and a clock decoder 13. Transmission system 12 includes a serializer 14 and a deserializer 15. Serializer 14 includes a phase-locked loop (PLL) 16, and deserializer 15 includes a clock recovery PLL 17.

Clock encoder 11 receives and analyzes a master clock (MasterClock) 18. Clock encoder 11 generates control data in the form of time stamps in a remote time stamp signal (RemoteTimeStamp) 19. Clock decoder 13 uses the time stamps to synthesize a remote controlled clock (RemoteControlledClock) 20. The time stamps are transmitted in remote time stamp signal 19 via synchronous serial data transmission system 12. In order to generate and to evaluate the time stamps, a synchronous time base is established by a system clock (SysClockTx) 21 on the transmitter side and by a system clock (SysClockRx) 22 on the receiver side. Master clock 18 and remote controlled clock 20 have the same average frequency and the same number of transitions over a predetermined period of time.

System 10 can be used remotely to control the synthesis of a system clock for data transmitted over a bidirectional multimedia link, as described in international patent application serial number PCT/EP2003/010522 entitled “System and Method for Forming a Bidirectional Multimedia Link”, for which the United States is a designated state. Although system 10 can be used with other data links, the bidirectional multimedia link of the aforementioned international patent application is described here as an exemplary use of system 10.

The aforementioned bidirectional multimedia link is a reliable, long-distance, serial bundle of links that can transmit Gigabits of data per second. The bandwidth of the bidirectional multimedia link can be increased by adding additional links or decreased by reducing the number of links. The bandwidth allocated to different types of multimedia data, such as audio, video and sideband data, can be changed by changing the bandwidth of the specific link of the bundle allocated to such data. The bidirectional multimedia link supports video formats ranging from VGA to UXGA, a panel technology that allows for true color support (16.7 million colors).

Multiplexing video data, audio data and sideband data over two independent links simplifies the interconnection technology dramatically. No skew between transmission channels need be controlled (de-skewing), and no data clock must be transmitted.

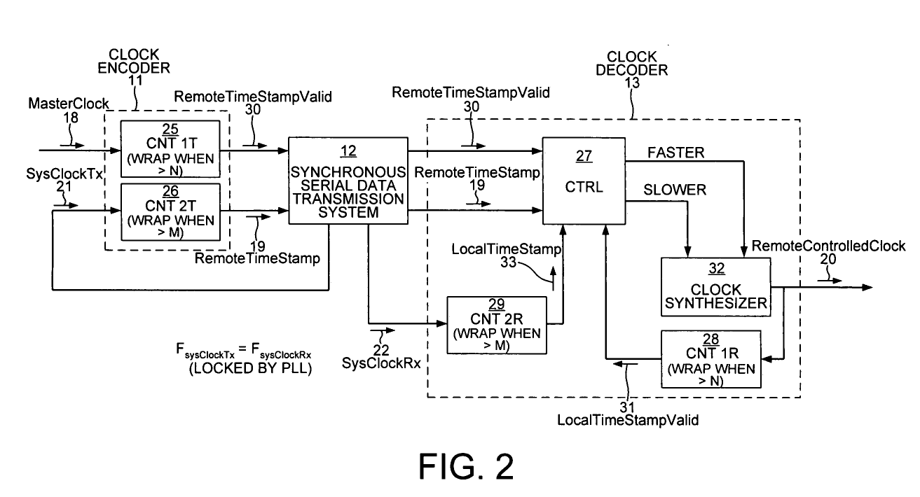

FIG. 2 shows clock encoder 11 and clock decoder 13 in more detail. Clock encoder 11 includes a first transmitter side counter (CNT 1T) 25 and a second transmitter side counter (CNT 2T) 26. Clock decoder 13 includes a controller (CTRL) 27, a first receiver side counter (CNT 1R) 28, a second receiver side counter (CNT 2R) 29, and a clock synthesizer 32. A common time base is formed by second transmitter side counter 26 on the transmitter side and by second receiver side counter 29 on the receiver side. Transmitter side counter 26 is clocked by transmitter side system clock (SysClockTx) 21. Receiver side counter 29 is clocked by receiver side system clock (SysClockRx) 22. Transmitter side system clock 21 and receiver side system clock 22 are locked to each other by clock recovery PLL 17 and are therefore synchronous to each other.

Within synchronous serial data transmission system 12, transmitter side system clock (SysClockTx) 21 is typically the serial data shift clock or a divided sub-clock. Receiver side system clock (SysClockRx) is the recovered serial data clock required for re-timing the serial data.

Second transmitter side counter 26 and second receiver side counter 29 are both wrap-around counters that wrap around if a certain count value M is exceeded. The values of second transmitter side counter 26 and second receiver side counter 29 are used to measure a predetermined period of time. The measurement of the time period is output in time stamps in the signals RemoteTimeStamp 19 and a localTimeStamp signal 33. The period of time is the value of second transmitter side counter 26 and second receiver side counter 29 that is present at the time first transmitter side counter 25 and first receiver side counter 28, respectively, exceed a certain count value N at which they wrap around. First transmitter side counter 25 generates a remote time stamp valid signal 30, and first receiver side counter 28 generates a local time stamp valid signal 31. First transmitter side counter 25 is clocked with master clock 18, and first receiver side counter 28 is clocked with remote controlled clock 20.

Master clock 18 is the clock at the transmitter side that is recovered (synthesized) at the receiver side. Remote controlled clock 20 is generated with the tunable clock synthesizer 32. A control algorithm ALGO1 continuously compares the remote time stamp in RemoteTimeStamp signal 19 from the transmitter side with the locally calculated local time stamp in LocalTimeStamp signal 33 from the receiver side. The control algorithm ALGO1 controls clock synthesizer 32 such that the remote controlled clock 20 has the same frequency and the same number of transitions as master clock 18.

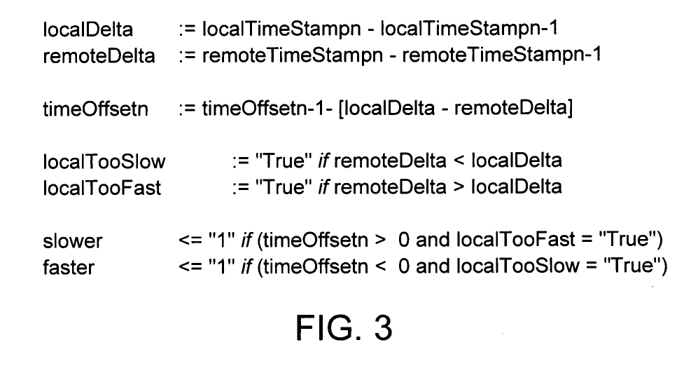

FIG. 3 shows the algorithm ALGO1. Controller 27 generates a local delta value (localDelta) using the algorithm ALGO1. The local delta value is a relative value of a local time stamp (localTimeStampn) at a time n and a local time stamp localTimeStampn−1 at a time n−1. FIG. 2 shows that the local time stamps localTimeStampn and localTimeStampn−1 are present on the receiver side.

In addition, controller 27 generates a remote delta value (remoteDelta) using the algorithm ALGO1. The remote delta value is a relative value of a remote time stamp (remoteTimeStampn) at a time n and a remote time stamp remoteTimeStampn−1 at a time n−1. FIG. 2 shows that the remote time stamps remoteTimeStampn and remoteTimeStampn−1 are present on the transmitter side. The relative values are used because second transmitter side counter 26 and second receiver side counter 29 are wrap-around counters so that a defined absolute value is not derivable.

After the local delta and remote delta values have been generated, controller 27 determines that the time offset time (timeoffsetn) is the time offset (timeOffsetn−1) minus the difference between the local delta and remote delta values. Controller 27 determines whether remote controlled clock 20 is too slow or too fast by setting the variables localTooSlow and localTooFast according to the condition defined in algorithm ALGO1 in FIG. 3. Finally, controller 27 controls clock synthesizer 32 to decrease the frequency of remote controlled clock 20 or to increase the frequency of remote controlled clock 20 if one of the two conditions in the last two lines of algorithm ALGO 1 is satisfied. Consequently, remote controlled clock (RemoteControlledClock) 20 is controlled to have the same frequency and the same amount of transitions as master clock (MasterClock) 18.

The serial bidirectional multimedia link with which system 10 can be used is now described in more detail.

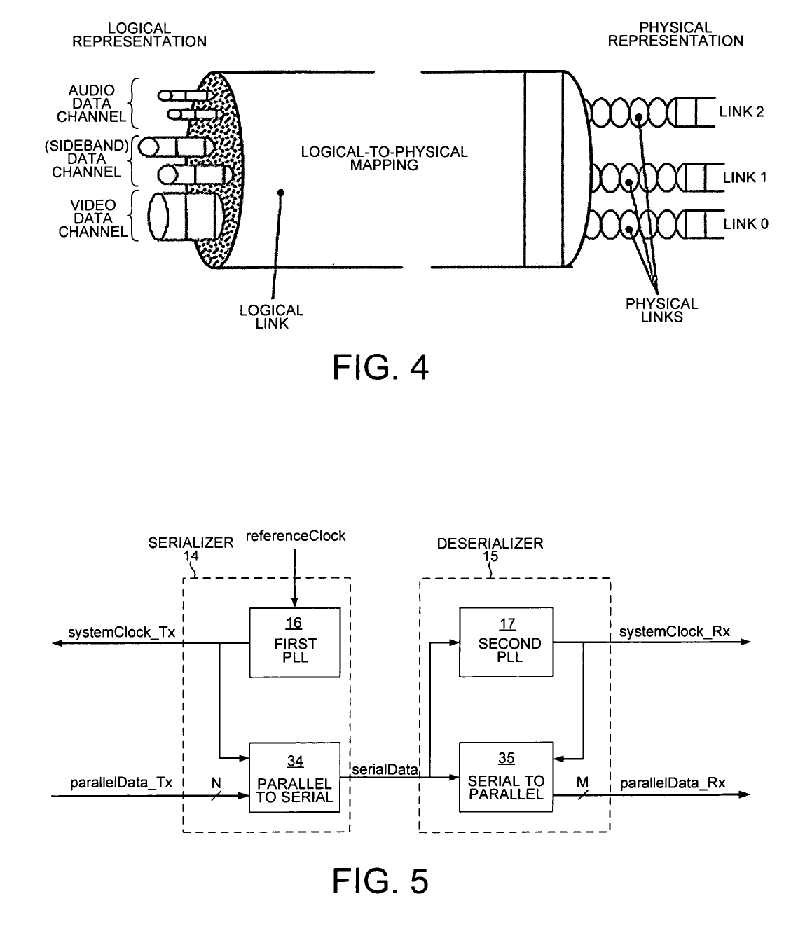

FIG. 4 shows a schematic view of a logical-to-physical mapping of the serial bidirectional multimedia link. The logical representation provides several logical channels for each different kind of data. Video data, audio data and sideband data are transmitted via the bidirectional multimedia link, and, thus, a video data channel, an audio data channel and a sideband data channel are provided. The video data, audio data and sideband data are mapped to several unidirectional physical links as shown in FIG. 4. Although three physical links (LINK) through LINK2) are shown, it should be noted that any number of links, including a single link can be used depending on the application and bandwidth requirements.

The bandwidth and latency requirements of such a transmission system are asymmetrical. When high bandwidth is required to transport video data from a video source to a video data consumer, latency is extremely relaxed. Audio data has low bandwidth and relaxed latency requirements. Both audio and video data form a unidirectional communication path from a video or audio source to a video or audio data consumer, which is the downstream direction. In addition, generic sideband data is transmitted to enable control data transfer or to check or change the status of data transfer. This communication path typically is bidirectional in the downstream and upstream direction and has medium bandwidth requirements. But this communication path might require extremely low latency.

The bandwidth provided by physical links for data transfer must be used as efficiently as possible. The high bandwidth requirements of video data in the range of 2 Gbit/s does not allow line coding with many overheads because data rates above 1 Gbit/s per physical link place excessive burdens on the application design.

The key electrical property of the physical link is the capability of AC coupling. The envisaged applications connect different systems separated by up to 100 meters using an STP cable. To avoid DC currents within the cable, AC coupling is required. This requires the serial data to be DC balanced.

The only communication paths between the transmitter and the receiver are the serial links themselves, as additional signaling might not be available. The receiver must be able to synchronize to the incoming data stream without additional mechanism after reset, power-up or cable disconnects.

FIG. 5 is a block diagram of a serializer/deserializer architecture of the serial bidirectional multimedia link of FIG. 4. The embodiment of FIG. 5 includes serializer 14 and deserializer 15. Serializer 14 includes a parallel-to-serial converter 34 and a first phase-locked loop (PLL) 16. Deserializer 15 includes a serial-to-parallel converter 35 and a second PLL 17. First PLL 16 receives a reference clock referenceClock. First PLL 16 outputs a system clock systemClock_Tx, which is received by the parallel-to-serial converter 34. Both second PLL 17 and serial-to-parallel converter 35 of deserializer 15 are coupled to a serial data input lead of deserializer 15. Second PLL 17 and serial-to-parallel converter 35 receive a serialData signal from parallel-to-serial converter 34 of serializer 14. Second PLL 17 outputs an output system clock systemClock_Rx. A clock input lead of the serial-to-parallel converter 35 receives systemClock_Rx.

First PLL 16 multiplies the reference clock referenceClock to obtain a high frequency clock systemClock_Tx. A parallel data signal parallelData Tx is serialized with the high frequency clock systemClock_Tx. A serial data signal serialData triggers second PLL 17 to recover the high frequency clock in order to obtain systemClock_Rx, which is a recovered high frequency clock. The serial data signal serialData is converted to a parallel format with the recovered high frequency clock systemClock_Rx.

The clock system of serializer 14 (based on the high frequency clock systemClock_Tx) and the clock system of deserializer 15 (based on the recovered high frequency clock systemClock_Rx) are synchronous to each other. While deserializer 15 performs a so-called bit alignment, the parallel data at the output of deserializer 15 is not aligned.

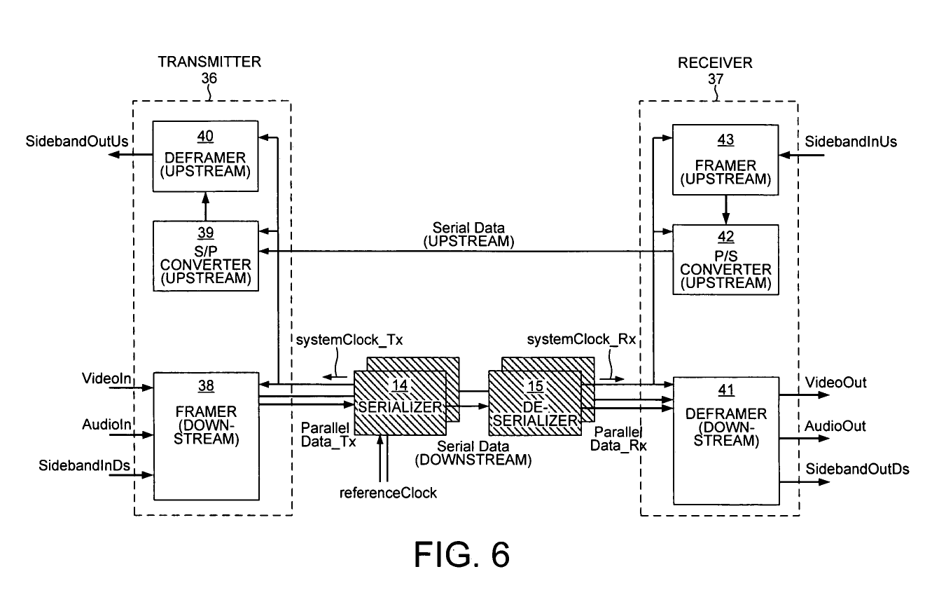

FIG. 6 is a more detailed schematic block diagram of the multimedia link architecture. The multimedia link architecture comprises a transmitter 36 and a receiver 37. Transmitter 36 comprises a downstream framer 38, an upstream serial-to-parallel converter 39 and an upstream deframer 40. Receiver 37 comprises a downstream deframer 41, an upstream parallel-to-serial converter 42 and an upstream framer 43. Transmitter 36 and receiver 37 are coupled through an appropriate number of serializers 14 and deserializers 15, as shown in FIG. 5. The number of serializers 14 and deserializers 15, and therefore the number of downstream physical links, is set based on the required bandwidth of the multimedia link architecture. The higher the required bandwidth, the higher the number of downstream physical links.

Input video data VideoIn, input audio data AudioIn and downstream sideband data SidebandInDs are received by downstream framer 38. Downstream framer 38 outputs parallel data ParallelData_Tx, which is received by serializer 14. Serializer 14 outputs a clock signal systemClock_Tx, which is received on a clock input lead of transmitter 36. Serializer 14 and deserializer 15 are connected to each other via one or more downstream serial data lines. Serial data SerialData (downstream) passes from serializer 14 to deserializer 15. Deserializer 15 is connected to downstream deframer 41. Deframer 41 receives parallel data parallelData_Rx from deserializer 15. Deserializer 15 outputs a clock signal systemClock_Rx, which is received on a clock input lead of receiver 37. Downstream deframer 41 outputs video data VideoOut, audio data AudioOut and downstream sideband data SidebandOutDs.

Upstream framer 43 receives upstream sideband data SidebandInUs. The output of upstream framer 43 is received by upstream parallel-to-serial converter 42. Upstream parallel-to-serial converter 42 is connected via an upstream serial data line SerialData (upstream) to the upstream serial-to-parallel converter 39. Serial data passes from upstream parallel-to-serial converter 42 to upstream serial-to-parallel converter 39. The output of serial-to-parallel converter 39 is received by upstream deframer 40. Upstream deframer 40 outputs upstream sideband data SidebandOutUs.

A key property of the multimedia link architecture is the clock system. The multimedia link architecture features a synchronous clock system at transmitter 36 and receiver 37. Serializer 14 generates a high frequency system clock systemClock_Tx used by transmitter 36. Furthermore, serializer 14 shifts the serial data out with the high frequency system clock systemClock_Tx. Deserializer 15 recovers the high frequency system clock systemClock_Tx of transmitter 36 from the serial bit stream and provides to receiver 37 a recovered high frequency system clock systemClock_Rx, which is synchronous with the high frequency system clock systemClock_Tx.

The clock system enables a lossless serial data bit recovery in the downstream direction without the need of stuffing bits (no bandwidth overhead for bit recovery). In addition, in the upstream direction, no clock recovery is required, as all clocks are synchronous. Also, in the upstream direction, a lossless serial data bit recovery is enabled without the need of stuffing bits (no bandwidth overhead for bit recovery).

In the downstream direction, multimedia data such as video data, audio data, and sideband data are fed into downstream framer 38. Downstream framer 38 multiplexes this multimedia data into a specific frame structure, adds information to this frame structure for frame alignment, which is performed at receiver 37, and performs line coding of the frame structure, which ensures a DC balanced serial data stream. The parallel frame data is serialized at serializer 14, transmitted via a serial transmission media such as an STP cable or a fiber optic cable and finally again converted to a parallel data format at deserializer 15. Parallel data output from deserializer 15 is not aligned, as the deserialization process starts randomly on the serial data stream. Downstream deframer 41 performs the alignment of the parallel frame data by utilizing specific information of the frame structure and unpacks the multimedia data such as video data, audio data, and sideband data.

In the upstream direction, sideband data is fed into upstream framer 43. Upstream framer 43 multiplexes this data into a specific frame structure and converts this data into DC balanced symbols that are converted to a serial data stream by parallel-to-serial converter 42, transmitted via a serial transmission media such as an STP cable or a fiber optic cable and finally again converted to a parallel data format at serial-to-parallel converter 39. Due to the synchronous nature of the overall clock system, no clock recovery is required in the upstream direction. The serial data can be sampled with the local high frequency clock. Due to runtime effects over the serial data transmission path and due to unavoidable phase shifts between the several clocks, a phase alignment is performed within parallel-to-serial converter 42. The parallel data that is output by serial-to-parallel converter 39 is not aligned, as the serial-to-parallel conversion process starts randomly on the serial data stream. Upstream deframer 40 performs the alignment of the parallel frame data and decodes the DC balanced symbols to obtain the sideband data SidebandOutUs.

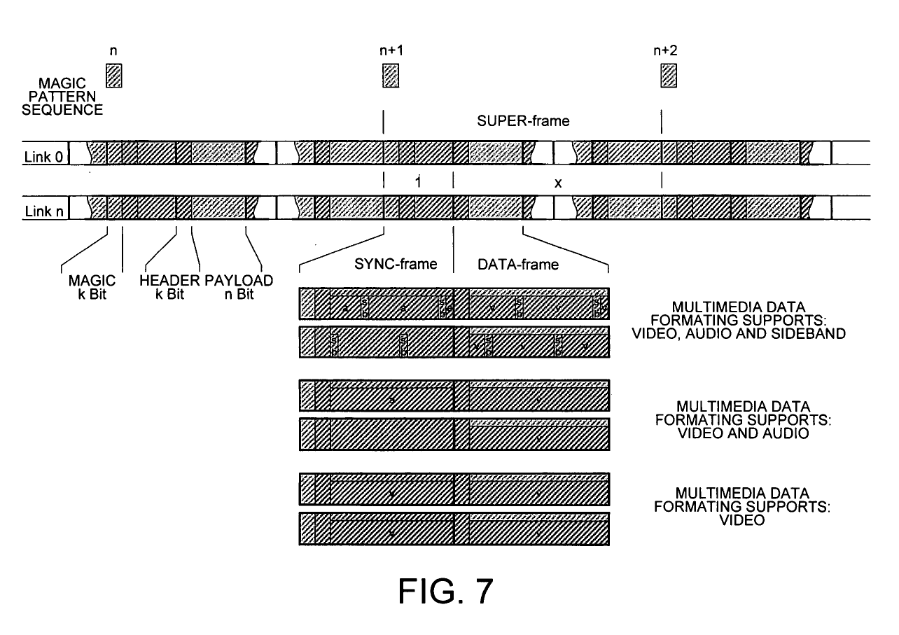

FIG. 7 illustrates the downstream frame structure of data transmitted via the bidirectional multimedia link. Due to the high bandwidth requirements in the downstream direction, the downstream frame structure should provide the highest degree of efficiency. Therefore, the least amount of data should be added to enable frame data alignment, to perform line coding and to select between different formats of the multimedia data. The frame structure should provide for high bandwidth and high latency data paths, as well as for low or medium bandwidth and extremely low latency data paths.

To support a bandwidth above about 1 GBit/s, scalable link architecture is used to keep the bandwidth per link around 1 Gbit/s. The downstream frame structure shown in FIG. 7 provides for multiple serial links. The basic element is a SUPER-frame. The SUPER-frame comprises one synchronization frame (SYNC-frame) followed by a first predetermined number (x) of data frames (DATA-frame). The synchronization frame (SYNC-frame) comprises a second predetermined number (k) of bits of a first section (called the magic section) and the predetermined number (k) of bits of a second section (called the header section) followed by a third predetermined number (n) minus the second predetermined number of bits (i.e., n−k) of a payload section. The data frame (DATA-frame) comprises the second predetermined number (k) of bits of a third section (called the header section) followed by the third predetermined number (n) of bits of a payload section.

The first section (magic section) of a synchronization frame (SYNC-frame) comprises a known and unique sequence of bit patterns indicating a start of the synchronization frame SYNC-frame. The second section (header section) of the synchronization frame (SYNC-frame) comprises control information about line coding and about the format of multimedia data within the payload data. The line coding allows for a DC-balanced serial data stream. Therefore, the payload data is conditionally inverted to maintain an equal number of “1” and “0” bits within the serial data stream over a certain period of time.

The second predetermined number (k) of bits defines the second section (header section) and results in 2k different binary patterns. A sub-set z of these 2k patterns defines valid frame headers, since not all possible bit permutations of k bits mark valid control information. The remaining or a subset of 2k−z bit patterns form a set of valid magic patterns MP1, . . . , Mpi. One of these magic patterns is chosen to have a special meaning and is called bogus magic pattern BMP. This bogus magic pattern BMP can never occur in the chosen line coding. A sequence over the valid magic patterns MP1, . . . , Mpi is defined.

To support different bandwidth allocation options for video data, audio data and sideband data, different payload formats exist, which are selected by control bits of the header section. To enable low latency and low jitter data paths for the sideband data, the payload bits that carry sideband data are equally spaced within the synchronization frame SYNC-frame and the data frame DATA-frame.

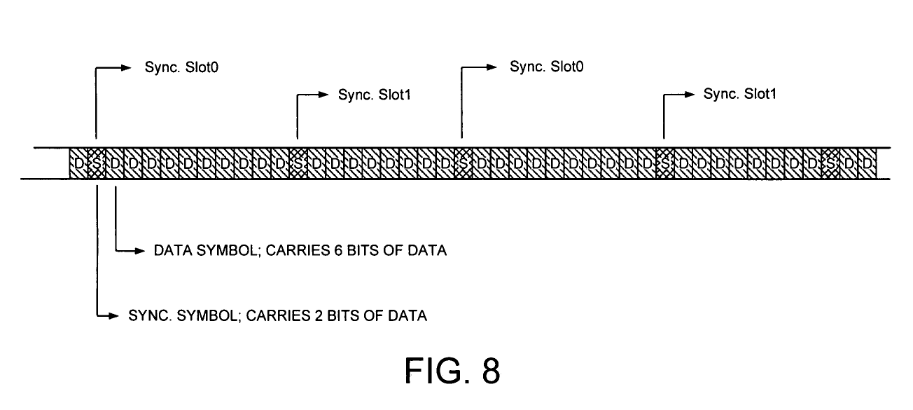

FIG. 8 is a schematic view of an upstream frame structure of data transmitted via the bidirectional multimedia link. Due to the medium bandwidth requirements in the upstream direction, the upstream frame structure need not provide for the highest efficiency. The upstream frame structure can be based on the ease and safety of frame alignment considering the need of phase alignment of the serial data stream.

FIG. 8 shows that the upstream frame structure provides for one serial link. The basic frame structure comprises a data sequence beginning with the synchronization symbol S, followed by a fourth predetermined number (e.g., 10) of data symbols D, followed by another synchronization symbol S, followed by a fifth predetermined number (e.g., 8) of data symbols D, and so on. Each symbol comprises 8 bits. The symbols are obtained by a specific 6B/8B-coding scheme. The asymmetrical structure of the upstream frames allows differentiating between two synchronization symbols. Each synchronization symbol S provides for two low-bandwidth data paths. The data symbols D provide for medium bandwidth data paths.

The architecture of the bidirectional multimedia link is highly scalable. As shown by FIG. 7, high scalability is achieved by different compositions of multimedia data within one serial link. In addition, high scalability is also achieved by adapting the number of serial links used in a respective application.

The bidirectional multimedia link can implement transmissions across up to 100 meters using a STP cable. In addition, the bidirectional multimedia link is tolerant against bit errors due to the frame structure of the data, even though the data is not protected by a error protection protocol, such as CRC or parity. Finally, the bidirectional multimedia link allows for a simplified physical layer protocol to perform framing and alignment.

Although the present invention has been described in connection with certain specific embodiments for instructional purposes, the present invention is not limited thereto. Accordingly, various modifications, adaptations, and combinations of various features of the described embodiments can be practiced without departing from the scope of the invention as set forth in the claims.

What is claimed is:

1. A system, comprising:
a clock encoder comprising a first transmitter side counter and a second transmitter side counter, wherein the first transmitter side counter counts up until a first predetermined number is exceeded and wraps around if the first predetermined number is exceeded, wherein the second transmitter side counter counts up until a second predetermined number is exceeded and wraps around if the second predetermined number is exceeded, wherein the first transmitter side counter receives a master clock having a frequency and a number of transitions, wherein the second transmitter side counter has a remote count value;
a clock decoder comprising a first receiver side counter and a second receiver side counter, wherein the first receiver side counter counts up until the first predetermined number is exceeded and wraps around if the first predetermined number is exceeded, wherein the second receiver side counter counts up until the second predetermined number is exceeded and wraps around if the second predetermined number is exceeded, wherein the second receiver side counter has a local count value;
a clock synthesizer that generates a remote controlled clock; and
a controller that controls the clock synthesizer such that the remote controlled clock has the frequency and the number of transitions of the master clock, wherein the second transmitter side counter outputs the remote count value as a remote time stamp when the first transmitter side counter wraps around, wherein the second receiver side counter outputs the local count value as a local time stamp when the first receiver side counter wraps around, and wherein the controller processes the remote time stamp and the local time stamp and generates control signals that control the clock synthesizer.

2. The system of claim 1, wherein the controller determines a first difference between a presently valid remote time stamp and a remote time stamp valid before the presently valid remote time stamp, wherein the controller determines a second difference between a presently valid local time stamp and a local time stamp valid before the presently valid local time stamp, wherein the controller determines a third difference that is a difference between the first difference and the second difference, and wherein the controller calculates a presently valid time offset by subtracting the third difference from a time offset valid before the presently valid time offset.

3. The system of claim 2, wherein the controller determines that the remote controlled clock is too slow when the second difference is smaller than the first difference, and wherein the controller determines that the remote controlled clock is too fast when the second difference is greater than the first difference.

4. The system of claim 2, wherein the remote controlled clock has a frequency, and wherein the controller increases the frequency of the remote controlled clock when the presently valid time offset has a value less than zero.

5. The system of claim 2, wherein the remote controlled clock has a frequency, and wherein the controller decreases the frequency of the remote controlled clock when the presently valid time offset has a value greater than zero.

6. A method, comprising:
counting up until a first predetermined number is exceeded and wrapping around when the first predetermined number is exceeded, wherein the counting is performed by a first transmitter side counter, wherein the first transmitter side counter receives a master clock having a frequency and a number of transitions;
counting up until a second predetermined number is exceeded and wrapping around when the second predetermined number is exceeded, wherein the counting is performed by a second transmitter side counter, wherein the second transmitter side counter has a remote count value;
counting up until the first predetermined number is exceeded and wrapping around when the first predetermined number is exceeded, wherein the counting is performed by a first receiver side counter;
counting up until the second predetermined number is exceeded and wrapping around when the second predetermined number is exceeded, wherein the counting is performed by a second receiver side counter, wherein the second receiver side counter has a local count value;
generating a remote controlled clock;
controlling the remote controlled clock such that the remote controlled clock has the frequency and the number of transitions of the master clock;
outputting the remote count value when the first transmitter side counter wraps around;
outputting the local count value when the first receiver side counter wraps around; and
generating control signals for controlling the remote controlled clock using the remote count value and the local count value.

7. The method of claim 6, wherein the controlling comprises determining a first difference between a presently valid local count value and a local count value valid before the presently valid local count value, determining a second difference between a presently valid remote count value and a remote count value valid before the presently valid remote count value, determining a third difference that is a difference between the first difference and the second difference, and calculating a presently valid time offset by subtracting the third difference from a time offset valid before the presently valid time offset.

8. The method of claim 7, wherein the controlling comprises determining that the remote controlled clock is too slow when the second difference is smaller than the first difference, and determining that the remote controlled clock is too fast when the second difference is greater than the first difference.

9. The method of claim 7, wherein the remote controlled clock has a frequency, and wherein the controlling increases the frequency of the remote controlled clock when the presently valid time offset has a value less than zero.

10. The method of claim 7, wherein the remote controlled clock has a frequency, and wherein the controlling decreases the frequency of the remote controlled clock when the presently valid time offset has a value greater than zero.

11. A system comprising:
a data transmission system connecting a transmitter side and a receiver side; and
means for synthesizing a remote controlled clock signal at the receiver side that is exactly synchronous to a master clock at the transmitter side, wherein the means synthesizes the remote controlled clock using a remote time stamp signal generated at the transmitter side and a local time stamp signal generated at the receiver side.

12. The system of claim 11, wherein the means comprises wrap-around counters.

13. The system of claim 11, wherein the data transmission system is a synchronous, serial data transmission system.

14. A system comprising:
a transmitter having a downstream framer, wherein the downstream framer receives first downstream multimedia data, adds frame information, and outputs first downstream framed parallel data;
a serializer that receives the first downstream framed parallel data and outputs first downstream framed serial data, wherein the serializer generates a first system clock used by the transmitter, and wherein the first downstream framed serial data comprises a synchronization frame followed by a predetermined number of data frames;
a deserializer that receives the first downstream framed serial data and outputs second downstream framed parallel data, wherein the deserializer recovers the first system clock from the first downstream framed serial data, wherein the deserializer generates a second system clock that is synchronous with the first system clock; and
a receiver having a downstream deframer, wherein the downstream deframer receives the second downstream framed parallel data and outputs second downstream multimedia data that corresponds to the first downstream multimedia data, and wherein the receiver uses the frame information for frame alignment of the second downstream multimedia data.

15. The system of claim 14, wherein downstream framer performs line coding of the first downstream framed parallel data to ensure that the first downstream framed serial data is a DC balanced serial data stream.

16. The system of claim 14, wherein the synchronization frame comprises a unique sequence of bit patterns indicating a start of the synchronization frame.
